(19) United States
(12) Patent Application Publication
(10) Pub. No.: US 2015/0151336 A1
(43) Pub. Date: Jun. 4, 2015

(54) NOZZLE AND APPARATUS FOR PROCESSING A SUBSTRATE INCLUDING THE SAME

(71) Applicant: SAMSUNG ELECTRONICS CO., LTD., Suwon-si (KR)

(72) Inventors: KYOUNG-SEOB KIM, Suwon-si (KR); SUCK-HYUN KANG, Hwaseong-si (KR); YONG-SUN KO, Suwon-si (KR); KYOUNG-HWAN KIM, Yongin-si (KR); KUN-TACK LEE, Suwon-si (KR); HYO-SAN LEE, Suwon-si (KR)

(21) Appl. No.: 14/301,515

(22) Filed: Jun. 11, 2014

(30) Foreign Application Priority Data
Nov. 29, 2013 (KR) 10-2013-0146954

(51) Int. Cl. B08B 3/02; H01L 21/67; H01L 21/02

(52) U.S. Cl. CPC B08B 3/02; H01L 21/02041; H01L 21/67017

(57) ABSTRACT

A nozzle may include a nozzle body, a conductive line and a resistance-measuring member. The nozzle body may include a plurality of injecting holes. The conductive line may be disposed along the injecting holes. The resistance-measuring member may be configured to measure a resistance of the conductive line to detect a deformation of the injecting holes.

### CROSS-RELATED APPLICATION

This application claims priority under 35 USC §119 to Korean Patent Application No. 10-2013-0146954, filed on Nov. 29, 2013, the disclosure of which is hereby incorporated by reference herein in its entirety.

1. Technical Field

Example embodiments relate to a nozzle and an apparatus for processing a substrate including the same. More particularly, example embodiments relate to a nozzle configured to inject a cleaning solution to a substrate, and an apparatus for processing a substrate including the nozzle.

2. Discussion of the Related Art

Generally, a cleaning apparatus for cleaning a semiconductor substrate may include a cleaning chamber, a spin chuck and a nozzle. The semiconductor substrate may be placed on the spin chuck. The nozzle may have a plurality of injecting holes configured to inject a cleaning solution to the semiconductor substrate.

According to related arts, the cleaning solution injected through the injecting holes may have a high pressure. Thus, the cleaning solution having the high pressure may generate deformations of the injecting holes such as cracks. The cleaning solution may be abnormally provided to the semiconductor substrate through the cracks. The abnormal cleaning solution may contaminate the semiconductor substrate.

### SUMMARY

Example embodiments provide a nozzle capable of accurately detecting deformation of injecting holes.

Example embodiments also provide an apparatus for processing a substrate including the above-mentioned nozzle.

According to an example embodiment, there may be provided a nozzle. The nozzle may include a nozzle body, a conductive line and a resistance-measuring member. The nozzle body may include a plurality of injecting holes. The conductive line may be disposed along the injecting holes. The resistance-measuring member may be configured to measure a resistance of the conductive line to detect a deformation of the injecting holes.

In an example embodiment, the resistance-measuring member may include a power supply configured to supply a current to the conductive line, and a resistance meter configured to measure a resistance of the conductive line.

In an example embodiment, the injecting holes may be arranged in at least one concentric circle.

In an example embodiment, the conductive line may be disposed along the concentric injecting holes.

In an example embodiment, the conductive line may include a plurality of openings in fluidic communication with each of the injecting holes.

In an example embodiment, the conductive line may include a conductive transparent oxide layer, a metal layer, etc.

In an example embodiment, the nozzle may further include a protecting layer configured to cover the conductive line.

In an example embodiment, the protecting layer may include a plurality of openings in fluidic communication with each of the injecting holes.

In an example embodiment, the protecting layer may include an insulating transparent layer.

In an example embodiment, the protecting layer may include a silicon oxide layer.

In an example embodiment, the nozzle body may include quartz.

According to an example embodiment, there may be provided an apparatus for processing a substrate. The apparatus may include a processing chamber, a chuck and a nozzle. The chuck may be disposed on a bottom surface of the processing chamber to support the substrate. The nozzle may include a nozzle body, a conductive line and a resistance-measuring member. The nozzle body may be disposed on an upper surface of the processing chamber. The nozzle body may include a plurality of injecting holes configured to inject a processing solution to the substrate. The conductive line may be disposed along the injecting holes. The resistance-measuring member may be configured to measure a resistance of the conductive line to detect a deformation of the injecting holes.

In an example embodiment, the chuck may include a spin chuck configured to rotate the substrate.

In an example embodiment, the processing solution may include a cleaning solution for cleaning the substrate.

In an example embodiment, the apparatus may further include a robot arm configured to transfer the nozzle to the chuck.

According to an example embodiment, a nozzle may be provided. The nozzle may include a nozzle body including a plurality of injecting holes disposed in at least one concentric circle and exposed through a lower surface of the nozzle body, a conductive line disposed on the lower surface of the nozzle body in at least one concentric circle and surrounding each of the injecting holes, and in which the conductive line may include a plurality of openings in fluid communication with each of the injecting holes, and a resistance-measuring member electrically connected to the conductive line.

The resistance-measuring member may include a power supply configured to supply a current to the conductive line, and a resistance meter configured to measure a resistance of the conductive line to detect a deformation of the injecting holes.

In addition, the nozzle may further include a protecting layer disposed on the lower surface of the nozzle body to cover the conductive line. The protecting layer may include a plurality of openings in fluidic communication with each of the injecting holes of the nozzle body and each of the openings of the conductive line.

According to example embodiments, when a deformation such as a crack is generated in the injecting holes, the resistance of the conductive line formed along the injecting holes may be changed. The resistance-measuring member may measure the resistance change to accurately detect the deformation of the injecting holes. Particularly, because the deformation of the injecting holes may be immediately shown as the resistance change of the conductive line, the deformation of the injecting holes may be detected in real time, so that immediate repair of the injecting holes may be feasible. As a result, an abnormal processing solution caused by the deformation of the injecting holes may not be provided to the substrate so that the substrate may not be contaminated.

### BRIEF DESCRIPTION OF THE DRAWINGS

Example embodiments can be understood in more detail from the following detailed description taken in conjunction with the accompanying drawings. FIGS. 1 to 8 represent non-limiting, example embodiments as described herein.

FIG. 1 is a cross-sectional view illustrating a nozzle in accordance with an example embodiment;

FIG. 2 is a bottom view illustrating the nozzle in FIG. 1;

FIG. 3 is an enlarged bottom of a portion “III” in FIG. 2;

FIG. 4 is a bottom view illustrating a normal injecting hole;

FIG. 5 is a bottom view illustrating a deformed injecting hole;

FIG. 6 is a cross-sectional view illustrating a nozzle in accordance with an example embodiment;

FIG. 7 is a bottom view illustrating the nozzle in FIG. 6; and

FIG. 8 is a cross-sectional view illustrating an apparatus for processing a substrate including the nozzle in FIG. 1.

### DETAILED DESCRIPTION OF EXAMPLE EMBODIMENTS

Example embodiments will be described more fully hereinafter with reference to the accompanying drawings. Example embodiments of the present invention may, however, be embodied in many different forms and should not be construed as limited to example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected.

Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Nozzle

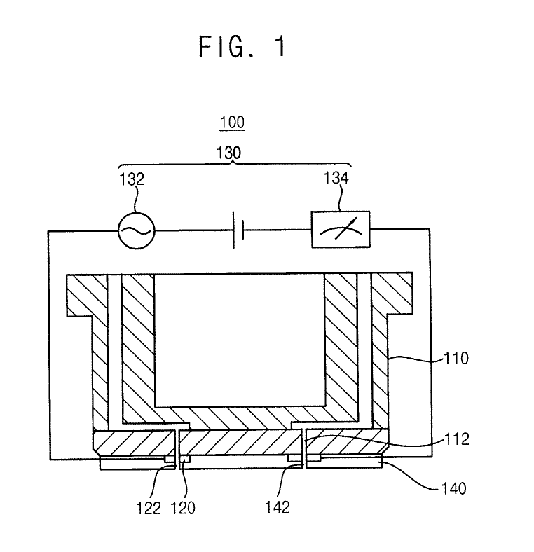

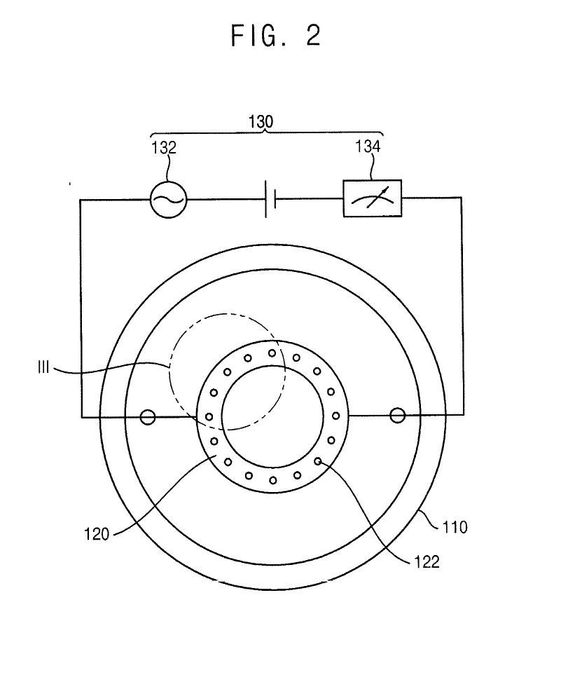

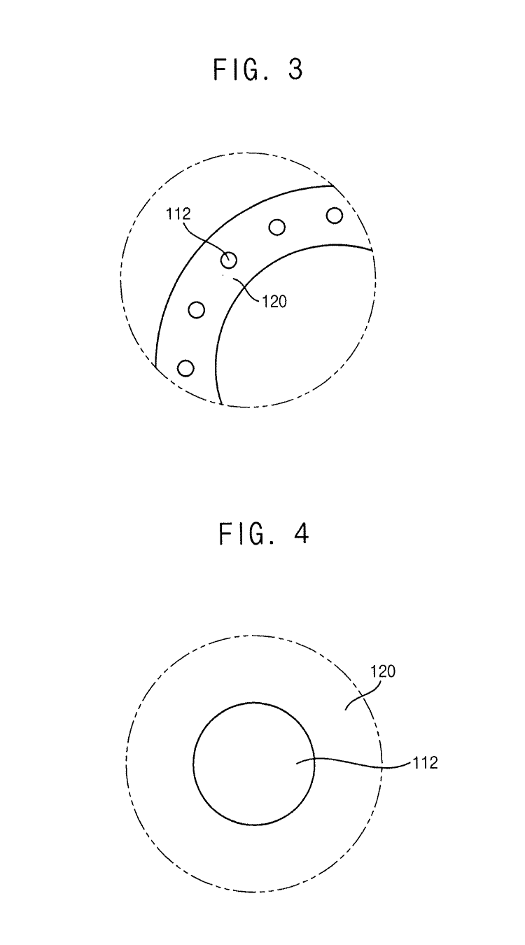

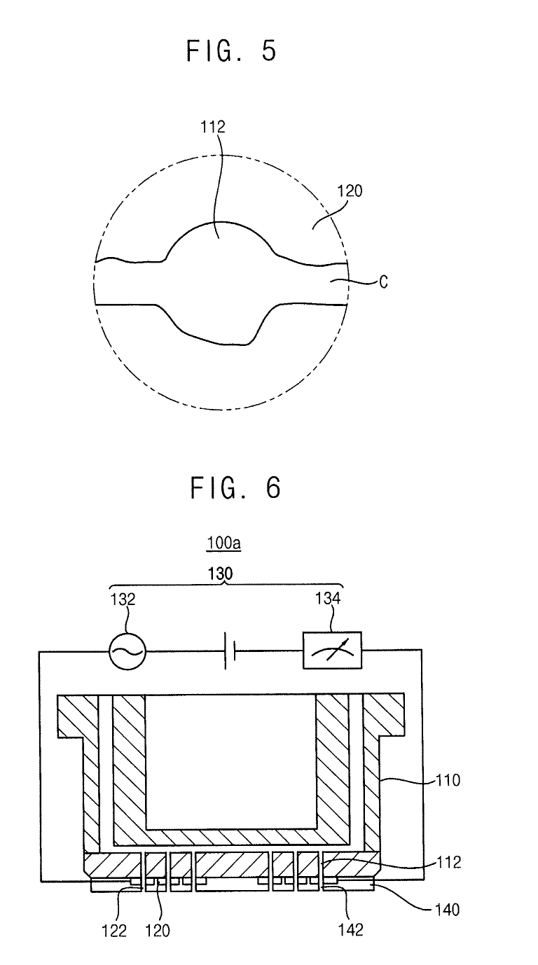

FIG. 1 is a cross-sectional view illustrating a nozzle in accordance with an example embodiment, FIG. 2 is a bottom view illustrating the nozzle in FIG. 1, FIG. 3 is an enlarged bottom of a portion “III” in FIG. 2, FIG. 4 is a bottom view illustrating a normal injecting hole, and FIG. 5 is a bottom view illustrating a deformed injecting hole.

Referring to FIGS. 1 to 3, a nozzle 100 of the present example embodiment may include, for example, a nozzle body 110, a conductive line 120, a resistance-measuring member 130 and a protecting layer 140.

The nozzle body 110 may have a plurality of injecting holes 112 configured to inject a processing solution having a high pressure to a substrate. Thus, the nozzle 100 may correspond to, for example, an ink jet type nozzle. In an example embodiment, the injecting holes 112 may be arranged in, for example, a concentric circle. The injecting holes 112 may be exposed through a lower surface of the nozzle body 110. The nozzle body 110 may include, for example, quartz.

The conductive line 120 may be formed on the lower surface of the nozzle body 110. The conductive line 120 may be arranged, for example, along the injecting holes 112. Thus, the conductive line 120 may be configured to, for example, surround each of the injecting holes 112.

In an example embodiment, because the injecting holes 112 may be arranged in the concentric circle, the conductive line 120 may also be arranged in a concentric circle. Therefore, an arrangement of the conductive line 120 may vary in accordance with an arrangement of the injecting holes 112. The conductive line 120 may have a plurality of openings 122 in fluidic communication with each of the injecting holes 112. In an example embodiment, the conductive line 120 may include, for example, a conductive transparent oxide layer, a metal layer, etc. The conductive line 120 may be formed by, for example, a physical vapor deposition (PVD) process, a chemical vapor deposition (CVD) process, etc.

The resistance-measuring member 130 may be electrically connected to the conductive line 120. The resistance-measuring member 130 may measure a resistance of the conductive line 120 to detect a deformation of the conductive line 120 such as, for example, a crack. In an example embodiment, the resistance-measuring member 130 may include, for example, a power supply 132 and a resistance meter 134. The power supply 132 may supply a current to the conductive line 120. The resistance meter 134 may measure the resistance of the conductive line 120.

Referring to FIG. 4, when the injecting holes 112 have a normal shape, resistance values of the normal conductive line 120 measured by the resistance meter 134 may be uniform. In contrast, referring to FIG. 5, when a crack is generated in the injecting holes 112, the conductive line 120 may be opened. Thus, resistance value of the conductive line 120 having the opened portion measured by the resistance meter 134 may be changed. The deformation of the injecting holes 112 such as the crack may be detected based on the resistance change of the conductive line 120. Particularly, because the power supply 132 may continuously supply the current to the conductive line 120, the deformation of the injecting holes 112 may be detected in real time. Thus, the abnormal injecting holes 112 may be rapidly repaired.

Referring back to FIG. 1, the protecting layer 140 may be formed on the lower surface of the nozzle body 110 to cover the conductive line 120. The protecting layer 140 may protect the conductive line 120 from the processing solution. In an example embodiment, the protecting layer 140 may have, for example, a plurality of openings 142 in fluidic communication with each of the injecting holes 112 of the nozzle body 110 and each of the openings 122 of the conductive line 120. Therefore, the processing solution may be injected through the injecting holes 112 of the nozzle body 110, the openings 122 of the conductive line 120 and the openings 142 of the protecting layer 140.

In an example embodiment, the openings 122 of the conductive line 120 and the openings 142 of the protecting layer 140 may be formed using, for example, a laser. Because the laser may be irradiated through the protecting layer 140, the protecting layer 140 may include a material for allowing the laser to pass through the protecting layer 140.

Further, to strengthen the adhesion strength between the protecting layer 140 and the nozzle body 110, the protecting layer 140 may include, for example, a material having strong adhesion strength with respect to the nozzle body 110. For example, the protecting layer 140 may include an insulating transparent layer such as, for example, a silicon oxide layer. Alternatively, the openings 122 of the conductive line 120 and the openings 142 of the protecting layer 140 may be formed by, for example, a micro electro mechanical system (MEMS). In this case, the protecting layer 140 may include, for example, an opaque material or a translucent material.

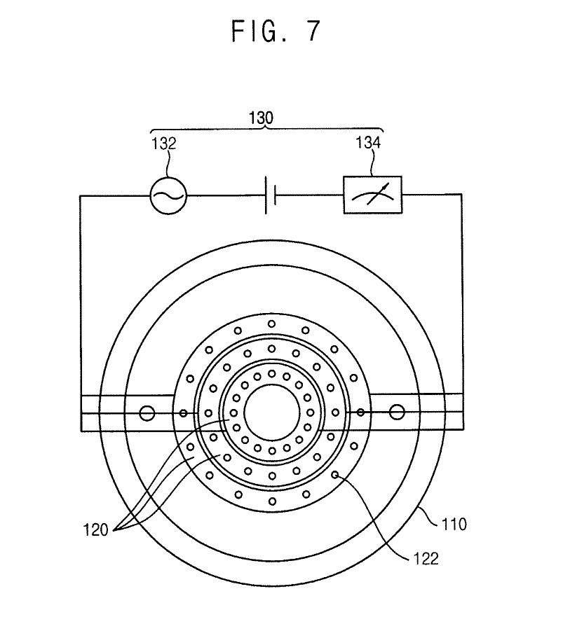

FIG. 6 is a cross-sectional view illustrating a nozzle in accordance with an example embodiment, and FIG. 7 is a bottom view illustrating the nozzle in FIG. 6.

A nozzle 100a of the present example embodiment may include elements substantially the same as those of the nozzle 100 in FIG. 1 except for the injecting holes and the conductive line. Thus, the same reference numerals may refer to the same elements and any further illustrations with respect to the same elements may be omitted herein for brevity.

Referring to FIGS. 6 and 7, injecting holes 112 may be, for example, arranged in three concentric circles. Thus, conductive lines 120 may also include, for example, three concentric circular lines along the injecting holes 112.

The resistance-measuring member 130 may be electrically connected to the three conductive lines 120. The resistance-measuring member 130 may measure the three conductive lines 120 to detect deformations of the injecting holes 112.

Alternatively, the injecting holes 112 and the conductive lines 120 may be arranged in, for example, two concentric circles or at least four concentric circles. Further, the injecting holes 112 and the conductive lines 120 may have other shapes such as, for example, a polygonal shape.

According to example embodiments, when a deformation such as a crack is generated in the injecting holes, the resistance of the conductive line formed along the injecting holes may be changed. The resistance-measuring member may measure the resistance change to accurately detect the deformation of the injecting holes. Particularly, because the deformation of the injecting holes may be immediately shown as the resistance change of the conductive line, the deformation of the injecting holes may be detected in real time, and thus immediate repair of the injecting holes may be feasible. As a result, an abnormal processing solution caused by the deformation of the injecting holes may not be provided to the substrate so that the substrate may not be contaminated.

Apparatus for Processing a Substrate

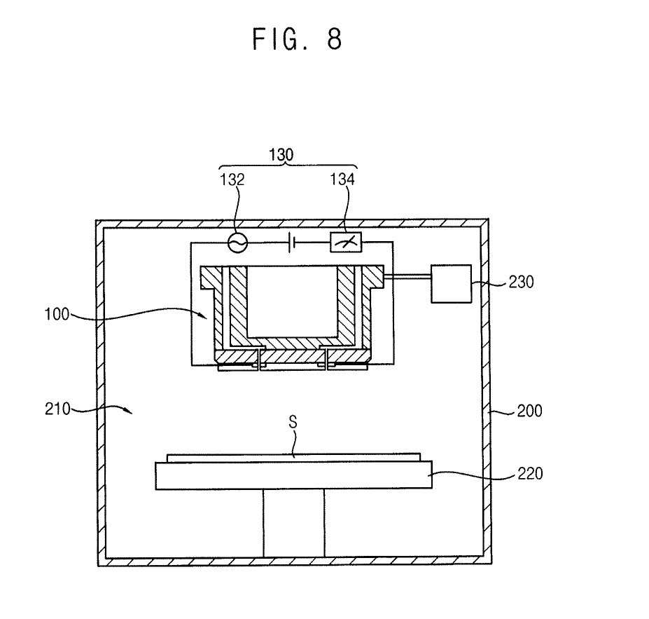

FIG. 8 is a cross-sectional view illustrating an apparatus for processing a substrate including the nozzle in FIG. 1.

Referring to FIG. 8, an apparatus 200 for processing a substrate in accordance with the present example embodiment may include, for example, a processing chamber 210, a chuck 220, a nozzle 100 and a robot arm 230.

The processing chamber 210 may process a semiconductor substrate S. In an example embodiment, the processing chamber 210 may correspond to, for example, a cleaning chamber for cleaning the semiconductor substrate S. Alternatively, the processing chamber 210 may include, for example, an etching chamber for wet etching a layer on the semiconductor substrate S.

The chuck 220 may be positioned on a bottom surface of the processing chamber 210. The chuck 220 may be configured to support the semiconductor substrate S. In an example embodiment, when the processing chamber 210 includes the cleaning chamber, the chuck 220 may include a spin chuck configured to rotate the semiconductor substrate S.

The nozzle 100 may inject a cleaning solution to the semiconductor substrate S on the chuck 220. When the processing chamber 210 includes the wet etching chamber, the nozzle 100 may inject an etching solution to the semiconductor substrate S. In an example embodiment, the nozzle 100 may include elements substantially the same as those of the nozzle 100 in FIG. 1. Thus, the same reference numerals may refer to the same elements and any further illustrations with respect to the same elements may be omitted herein for brevity.

The robot arm 230 may, for example, horizontally rotate the nozzle 100. When the semiconductor substrate S is placed on the chuck 220, the robot arm 230 may rotate the nozzle 100 toward the chuck 220. Thus, the nozzle 100 may be positioned over the semiconductor substrate S.

Alternatively, when the processing chamber 210 includes the wet etching chamber, the apparatus 200 may not include the robot arm 230.

According to example embodiments, when a deformation such as a crack is generated in the injecting holes, the resistance of the conductive line formed along the injecting holes may be changed. The resistance-measuring member may measure the resistance change to accurately detect the deformation of the injecting holes. Particularly, because the deformation of the injecting holes may be immediately shown as the resistance change of the conductive line, the deformation of the injecting holes may be detected in real time, and thus immediate repair of the injecting holes may be feasible. As a result, an abnormal processing solution caused by the deformation of the injecting holes may not be provided to the substrate so that the substrate may not be contaminated.

Having described example embodiments of the present invention, it is further noted that it is readily apparent to those of ordinary skill in the art that various modifications may be made without departing from the spirit and scope of the invention which is defined by the metes and bounds of the appended claims.

What is claimed is:

1. A nozzle comprising:
a nozzle body including a plurality of injecting holes;
a conductive line disposed along the injecting holes; and
a resistance-measuring member configured to measure a resistance of the conductive line to detect a deformation of the injecting holes.

2. The nozzle of claim 1, wherein the resistance-measuring member comprises:
a power supply configured to supply a current to the conductive line; and
a resistance meter configured to measure a resistance of the conductive line.

3. The nozzle of claim 1, wherein the injecting holes are disposed in at least one concentric circle.

4. The nozzle of claim 3, wherein the conductive line is disposed along the concentric injecting holes.

5. The nozzle of claim 1, wherein the conductive line includes a plurality of openings in fluidic communication with each of the injecting holes.

6. The nozzle of claim 1, wherein the conductive line comprises one of a conductive transparent oxide layer or a metal layer.

7. The nozzle of claim 1, further comprising a protecting layer configured to cover the conductive line.

8. The nozzle of claim 7, wherein the protecting layer includes a plurality of openings in fluidic communication with each of the injecting holes.

9. The nozzle of claim 7, wherein the protecting layer comprises an insulating transparent layer.

10. The nozzle of claim 9, wherein the protecting layer comprises a silicon oxide layer.

11. The nozzle of claim 1, wherein the nozzle body comprises quartz.

12. An apparatus for processing a substrate, the apparatus comprising:
a processing chamber;
a chuck disposed on a bottom surface of the processing chamber to support the substrate; and
a nozzle including a nozzle body, a conductive line and a resistance-measuring member, the nozzle body disposed on an upper surface of the processing chamber and including a plurality of injecting holes configured to inject a processing solution to the substrate, the conductive line disposed along the injecting holes, and the resistance-measuring member configured to measure a resistance of the conductive line to detect a deformation of the injecting holes.

13. The apparatus of claim 12, wherein the chuck comprises a spin chuck configured to rotate the substrate.

14. The apparatus of claim 12, wherein the processing solution comprises a cleaning solution for cleaning the substrate.

15. The apparatus of claim 12, further comprising a robot arm configured to transfer the nozzle to the chuck.

16. The apparatus of claim 12, wherein the substrate is a semiconductor substrate.

17. A nozzle comprising:
a nozzle body including a plurality of injecting holes disposed in at least one concentric circle and exposed through a lower surface of the nozzle body;
a conductive line disposed on the lower surface of the nozzle body in at least one concentric circle and surrounding each of the injecting holes, wherein the conductive line includes a plurality of openings in fluid communication with each of the injecting holes;
a resistance-measuring member electrically connected to the conductive line, wherein the resistance-measuring member includes a power supply configured to supply a current to the conductive line, and a resistance meter configured to measure a resistance of the conductive line to detect a deformation of the injecting holes; and
a protecting layer disposed on the lower surface of the nozzle body to cover the conductive line, wherein the protecting layer includes a plurality of openings in fluidic communication with each of the injecting holes of the nozzle body and each of the openings of the conductive line.

18. The nozzle of claim 17, wherein the protecting layer includes one of an opaque material or a translucent material.

19. The nozzle of claim 17, wherein the injecting holes are disposed in a first concentric circle, a second concentric circle, and a third concentric circle, wherein the conductive line includes a first conductive line disposed in a first concentric circle surrounding the injecting holes, a second conductive line disposed in a second concentric circle surrounding the injecting holes and a third conductive line disposed in a third concentric circle surrounding the injecting holes, and wherein the resistance-measuring member is electrically connected to each of the first conductive line, the second conductive line and the third conductive line.

20. The nozzle of claim 17, wherein the nozzle body corresponds to an ink jet type nozzle.
